(19) United States
(12) Patent Application Publication
(10) Pub. No.: US 2025/0169248 A1
(43) Pub. Date: May 22, 2025

(54) DISPLAY DEVICE

(71) Applicant: Samsung Display Co., LTD., Yongin-si (KR)

(72) Inventors: Sung Hwan HONG, Yongin-si (KR); Suk Hoon KANG, Yongin-si (KR); Jeong Soo KIM, Yongin-si (KR); Beom Soo SHIN, Yongin-si (KR); Min Seok LEE, Yongin-si (KR)

(73) Assignee: Samsung Display Co., LTD., Yongin-si (KR)

(21) Appl. No.: 18/763,136

(22) Filed: Jul. 3, 2024

(30) Foreign Application Priority Data
Nov. 22, 2023 (KR) 10-2023-0163530

(51) Int. Cl. H01L 33/50; H01L 25/075; H01L 33/62

(52) U.S. Cl. CPC H10H 20/8512; H01L 25/0753; H10H 20/857

(57) ABSTRACT

A display device that includes a base layer, a display layer disposed on the base layer and including a light emitting element, a conductive pattern layer disposed on the display layer, and a bank disposed on the display layer, the bank protruding in a thickness direction of the base layer and surrounding at least a portion of an area. The bank covers the conductive pattern layer and includes a first bank scatterer and a second bank scatterer, the second bank scatterer having a size different from that of the first bank scatterer.

### CROSS-REFERENCE TO RELATED APPLICATIONS

This application claims priority under 35 U.S.C. § 119 from Korean Patent Application No. 10-2023-0163530 filed on Nov. 22, 2023 in the Korean Intellectual Property Office, the entire contents of which are incorporated herein by reference.

### BACKGROUND

### 1. Technical Field

The disclosure relates to a display device.

### 2. Description of the Related Art

Recently, as interest in displaying information increases, research and development on a display device is continuously being conducted. As an application field of the display device is expanded, the display device may be required to include a panel structure with further improved light output efficiency.

In order to perform a manufacturing process of the display device, various processes may be applied. For example, an exposure process may be performed to pattern a conductive layer and/or an insulating layer.

In case that the exposure process is performed, a position and the like of a mask may be adjusted based on a position of an alignment key provided on a panel for manufacturing the display device. Accordingly, in order to properly perform a manufacturing process, the alignment key may be required to be appropriately recognized by process equipment.

### SUMMARY

One aspect of the disclosure is to provide a display device with improved light output efficiency and display quality.

One aspect of the disclosure is to provide a display device in which an alignment key structure may be appropriately recognized and thus a manufacturing process of the display device may be normally performed.

According to an embodiment, a display device may include a base layer, a display layer disposed on the base layer and including a light emitting element, a conductive pattern layer disposed on the display layer, and a bank disposed on the display layer, the bank protruding in a thickness direction of the base layer, and the bank surrounding at least a portion of an area. The bank may cover the conductive pattern layer, the bank may include a first bank scatterer and a second bank scatterer, the second bank scatterer may have a size different from that of the first bank scatterer.

According to an embodiment, the bank may transmit light of a near infrared wavelength band.

According to an embodiment, the bank may have a light transmittance of a range of about 13% to about 15% with respect to light having a wavelength of about 880 nm.

According to an embodiment, the bank may include a bank base including a photosensitive material.

According to an embodiment, each of the first bank scatterer and the second bank scatterer may include at least one material selected from a group of titanium oxide (TiOₓ), silica (SiOₓ) (for example, a silica bead, hollow silica, and the like), zirconium oxide (ZrOₓ), aluminum oxide (AlₓO_{y}), indium oxide (InₓO_{y}), zinc oxide (ZnOₓ), tin oxide (SnOₓ), cerium oxide (CeOₓ), indium tin oxide (ITO), antimony tin oxide (ATO), and antimony oxide (SbₓO_{y}).

According to an embodiment, a size of the first bank scatterer may be in a range of about 200 nm to about 300 nm.

According to an embodiment, a size of the second bank scatterer may be in a range of about 100 nm to about 200 nm.

According to an embodiment, the bank may have a thickness in a range of about 10 μm to about 11 μm, and each of the first bank scatterer and the second bank scatterer may be included in a range of about 6% by weight to about 7% by weight with respect to a solid content of the bank.

According to an embodiment, the bank may have a thickness in a range of about 4 μm to about 6 μm, and each of the first bank scatterer and the second bank scatterer may be included in a range of about 12% by weight to about 16% by weight with respect to a solid content of the bank.

According to an embodiment, the bank may have a thickness in a range of about 2 μm to about 4 μm, and each of the first bank scatterer and the second bank scatterer may be included in a range of about 20% by weight to about 24% by weight with respect to a solid content of the bank.

According to an embodiment, the bank may have a thickness in a range of about 0.5 μm to about 1.5 μm, and each of the first bank scatterer and the second bank scatterer may be included in a range of about 0.01% by weight to about 60% by weight with respect to a solid content of the bank.

According to an embodiment, the conductive pattern layer may function as an alignment key during an exposure process for manufacturing the display device.

According to an embodiment, the display device may further include a color conversion layer disposed in the area surrounded by the bank, the color conversion layer may include a quantum-dot.

According to an embodiment, the display device may further include sub-pixels forming sub-pixel areas where light of a color may be respectively provided. The sub-pixel areas may include a first sub-pixel area, a second sub-pixel area, and a third sub-pixel area. The sub-pixels may include a first sub-pixel, a second sub-pixel, and a third sub-pixel. The bank may be disposed between the sub-pixel areas. The display device may further include a first color conversion layer disposed in the first sub-pixel area and including a first quantum-dot, a second color conversion layer disposed in the second sub-pixel area and including a second quantum-dot, and a scattering layer disposed in the third sub-pixel area and including a scatterer.

According to an embodiment, the conductive pattern layer and the bank may be in contact with each other.

According to an embodiment, the area may correspond to one of a color conversion layer and a scattering layer.

According to an embodiment, the bank simultaneously increases reflectance of a visible light produced by the display layer and transmits a near infrared light to detect a location of the alignment key by detecting a reflection of the near infrared light from the alignment key.

According to an embodiment, a size of the first bank scatterer may be in a range of about 200 nm to about 300 nm and a size of the second bank scatterer may be in a range of about 100 nm to about 200 nm.

According to an embodiment of the disclosure, a display device with improved light output efficiency and display quality may be provided.

According to an embodiment of the disclosure, a display device in which an alignment key structure may be appropriately recognized and thus a manufacturing process of the display device may be normally performed may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIGS. 2 and 3 are schematic cross-sectional views illustrating a display device according to an embodiment;

FIG. 4 is a schematic diagram illustrating a bank according to an embodiment;

FIG. 5 is a schematic diagram illustrating a partial step of a manufacturing process of a display device according to an embodiment;

FIG. 6 is a graph illustrating Experimental Example 1; and

FIG. 7 is a graph illustrating Experimental Example 2.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure relates to a display device. Hereinafter, a display device according to an embodiment is described with reference to the accompanying drawings.

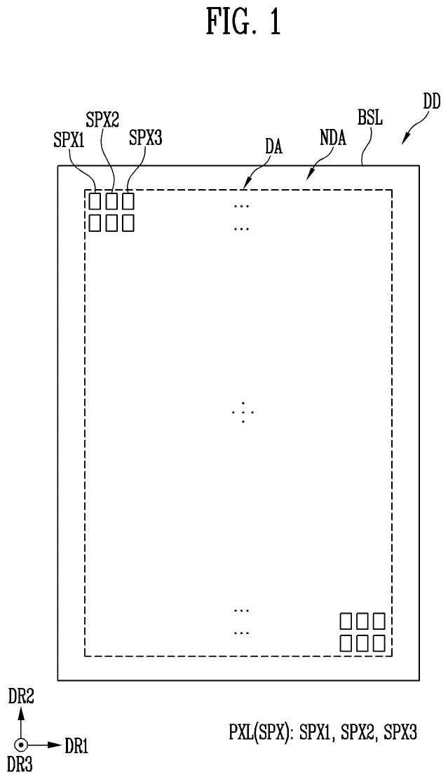

FIG. 1 is a schematic plan view illustrating a display device according to an embodiment.

Referring to FIG. 1, the display device DD may include a base layer BSL and a pixel PXL disposed on the base layer BSL. Although not shown in the drawing, the display device DD may further include a driving circuit part (for example, a scan driver and a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. The base layer BSL may be rigid, a flexible substrate, or a film. For example, the base layer BSL may include a glass material. The base layer BSL may include a silicon material. The base layer BSL may include polyimide. However, the disclosure may not be limited thereto

The display area DA may mean an area where the pixel PXL may be disposed. The non-display area NDA may mean an area where the pixel PXL may not be disposed. The driving circuit part, the line, and the pads electrically connected to the pixel PXL of the display area DA may be disposed in the non-display area NDA.

According to an embodiment, the pixel PXL (or sub-pixels SPX) may be arranged according to a stripe or PENTILE™ arrangement structure, but may not be limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form a pixel part configured to emit light of various colors.

For example, each of the first sub-pixel SPX1, the second sub-pixel SPX2, and the third sub-pixel SPX3 may emit light of a color.

For example, the first sub-pixel SPX1 may be a red pixel emitting light of red (for example, first color), the second sub-pixel SPX2 may be a green pixel emitting light of green (for example, second color), and the third sub-pixel SPX3 may be a blue pixel emitting light of blue (for example, third color). The red pixel may provide light in a wavelength range of about 600 nm to about 750 nm. The green pixel may provide light in a wavelength range of about 480 nm to about 560 nm. The blue pixel may provide light in a wavelength range of about 370 nm to about 460 nm.

According to an embodiment, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel part may not be limited to a specific example.

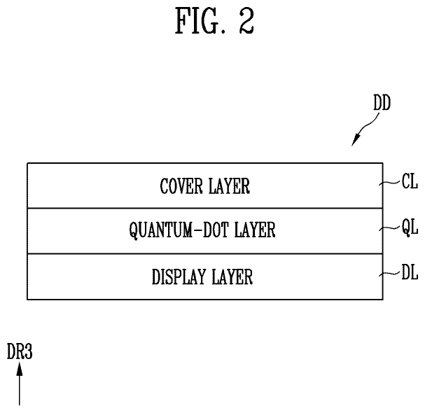

With reference to FIGS. 2 to 5, a display device DD including a bank BNK according to an embodiment may be described.

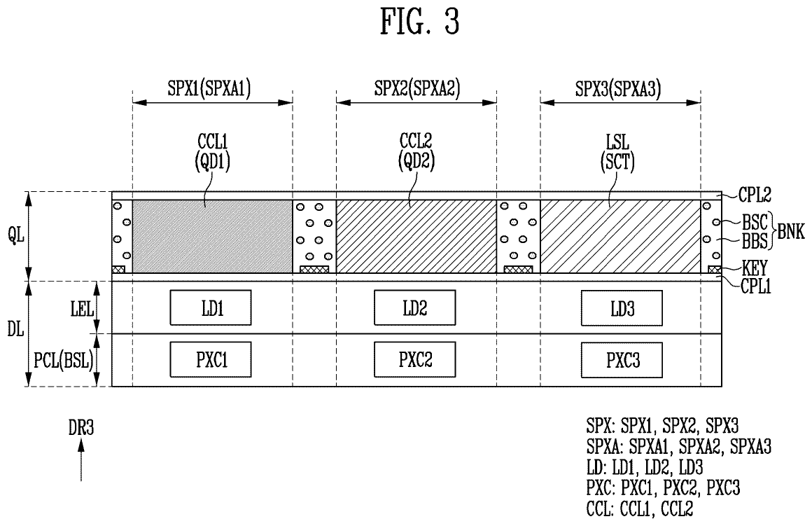

FIGS. 2 and 3 are schematic cross-sectional views illustrating a display device according to an embodiment. FIG. 2 is a schematic cross-sectional view illustrating the display device DD, and FIG. 3 is a schematic cross-sectional view illustrating a display layer DL and a quantum-dot layer QL among layers of the display device DD. FIG. 3 shows a cross-sectional structure of the display device DD in the display area DA.

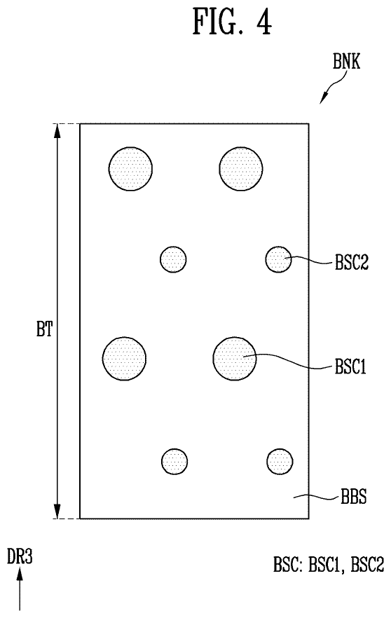

FIG. 4 is a schematic diagram illustrating a bank according to an embodiment.

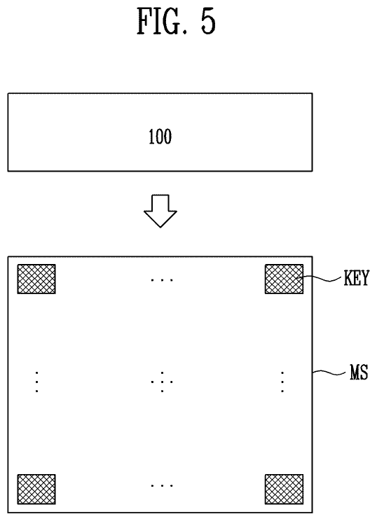

FIG. 5 is a schematic diagram illustrating a partial step of a manufacturing process of a display device according to an embodiment. FIG. 5 schematically shows a process step in which an exposure process may be performed based on a conductive pattern layer KEY disposed under the bank BNK according to an embodiment.

Referring to FIGS. 2 to 5, the display device DD according to an embodiment may include the display layer DL, the quantum-dot layer QL, and a cover layer CL. The quantum-dot layer QL may include a bank layer.

The display layer DL may be configured to emit light. The display layer DL may form a base on which the quantum-dot layer QL may be disposed.

The display layer DL may include a pixel-circuit layer PCL including a base layer BSL and a light-emitting-element layer LEL including a light emitting element LD.

The base layer BSL may form a base on which a pixel circuit PXC may be disposed. The pixel circuit PXC may be disposed on the base layer BSL and may be configured to drive the light emitting element LD. The pixel-circuit layer PCL may include conductive layers and insulating layers, and the conductive layers may form the pixel circuit PXC.

According to an embodiment, the pixel circuit PXC may include a first pixel circuit PXC1 configured to drive the first sub-pixel SPX1 (for example, a first light emitting element LD1), a second pixel circuit PXC2 configured to drive the second sub-pixel SPX2 (for example, a second light emitting element LD2), and a third pixel circuit PXC3 configured to drive the third sub-pixel SPX3 (for example, a third light emitting element LD3).

The light-emitting-element layer LEL may be disposed on the pixel-circuit layer PCL. According to an embodiment, the light-emitting-element layer LEL may include the light emitting element LD. The light emitting element LD may be an inorganic light emitting diode including an inorganic semiconductor, and the light emitting element LD may be an organic light emitting diode (OLED) including an organic material. However, the disclosure may not be limited to a specific example.

The light emitting element LD may be electrically connected to the pixel circuit PXC. The light emitting element LD may emit light based on an electrical signal (for example, current intensity) provided from the pixel circuit PXC. The light emitting element LD may include the first light emitting element LD1 included in the first sub-pixel SPX1, the second light emitting element LD2 included in the second sub-pixel SPX2, and the third light emitting element LD3 included in the third sub-pixel SPX3.

According to an embodiment, sub-pixel areas SPXA respectively corresponding to the sub-pixels SPX may be formed in the display area DA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3.

The quantum-dot layer QL may be disposed on the display layer DL (for example, the light-emitting-element layer LEL). The quantum-dot layer QL may be a layer where the bank BNK may be disposed.

The quantum-dot layer QL may include a first capping layer CPL1, a conductive pattern layer KEY, the bank BNK, a color conversion layer CCL, a scattering layer LSL, and a second capping layer CPL2. The color conversion layer CCL may include a first color conversion layer CCL1 and a second color conversion layer CCL2.

The first capping layer CPL1 may be disposed on the light-emitting-element layer LEL. According to an embodiment, the first capping layer CPL1 may cap a lower portion of each of the first color conversion layer CCL1, the second color conversion layer CCL2, and the scattering layer LSL.

According to an embodiment, the first capping layer CPL1 may form a base on which the conductive pattern layer KEY may be disposed. For example, the first capping layer CPL1 may contact the conductive pattern layer KEY.

According to an embodiment, the first capping layer CPL1 may be provided over the first to third sub-pixels SPX1, SPX2, and SPX3. According to an embodiment, the first capping layer CPL1 may be an inorganic layer and may include at least one of a group of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}). However, the disclosure may not be limited thereto.

The conductive pattern layer KEY may be disposed between the sub-pixel areas SPXA. According to an embodiment, the conductive pattern layer KEY may not overlap the sub-pixel areas SPXA in a plan view.

The conductive pattern layer KEY may be covered by the bank BNK. The conductive pattern layer KEY may be in contact with the bank BNK. The conductive pattern layer KEY may overlap the bank BNK in a plan view.

According to an embodiment, the conductive pattern layer KEY may be disposed on the display layer DL (for example, the light-emitting-element layer LEL). The conductive pattern layer KEY may be disposed on the first capping layer CPL1.

However, a position of the conductive pattern layer KEY may not be necessarily limited to the above-described example. In some embodiments, the conductive pattern layer KEY may not be disposed in the quantum-dot layer QL, and the conductive pattern layer KEY and a conductive layer formed in the pixel-circuit layer PCL may be disposed on a same layer.

The conductive pattern layer KEY may include a conductive material. For example, the conductive pattern layer KEY may include titanium-copper alloy (TiCu) or aluminum (Al). However, the disclosure may not be limited thereto.

According to an embodiment, the conductive pattern layer KEY may perform an alignment key function when a process (for example, an exposure process) for manufacturing the display device DD is performed.

For example, the conductive pattern layer KEY may be an alignment key (for example, a wafer alignment key) for performing the exposure process during the manufacturing process of the display device DD. The alignment key may be for alignment between masks. The alignment key may be for alignment between the mask and a mother substrate MS in case that the exposure process is performed.

For example, in order to manufacture the display device DD, after a photoresist layer and an exposure mask may be disposed on the mother substrate MS, an exposure device 100 may perform the exposure process. At this time, a position between the exposure mask and the mother substrate MS may be required to be closely defined. According to an embodiment, a position of the exposure mask and the mother substrate MS may be determined based on a position of the conductive pattern layer KEY.

According to an embodiment, a conductive layer and an insulating layer may be patterned on the mother substrate MS, multiple configurations for forming the display device DD may be disposed, and thus the display device DD according to an embodiment may be provided. Ultimately, the conductive pattern layer KEY according to an embodiment may be provided, and thus the manufacturing process of the display device DD, including the exposure process, may be appropriately performed.

According to an embodiment, the exposure device 100 may determine the position of the exposure mask and the mother substrate MS based on the position of the conductive pattern layer KEY. For example, the exposure device 100 may include a light transmitting part and a light receiving part. The light transmitting part of the exposure device 100 may provide light of a wavelength band to the mother substrate MS, and the light receiving part may recognize an interaction (for example, reflection or the like) by the conductive pattern layer KEY of provided light to obtain position information on the conductive pattern layer KEY and the mother substrate MS.

According to an embodiment, light applied by the exposure device 100 to obtain information on the position of the conductive pattern layer KEY may include a near infrared (a near infrared radiation (NIR)) wavelength band. For example, the NIR wavelength band may include a wavelength range including at least about 880 nm. According to an embodiment, the NIR wavelength band may include a wavelength band in a range of about 760 nm to about 1400 nm. According to an embodiment, the NIR wavelength band may include a wavelength band in a range of about 800 nm to about 960 nm.

In order for the exposure device 100 to closely determine the position of the exposure mask and the like based on the position of the conductive pattern layer KEY, the light applied by the exposure device 100 may be required to be applied to the conductive pattern layer KEY.

According to an embodiment, the bank BNK disposed on the conductive pattern layer KEY may transmit the light applied by the exposure device 100, and thus the conductive pattern layer KEY may function as an alignment key during the exposure process.

The bank BNK may be disposed on the display layer DL (for example, the light-emitting-element layer LEL). The bank BNK may be disposed between the sub-pixel areas SPXA.

According to an embodiment, the bank BNK may overlap the conductive pattern layer KEY in a plan view. The bank BNK may cover the conductive pattern layer KEY. The bank BNK may be in contact with the conductive pattern layer KEY.

The bank BNK may surround at least a portion of an area. For example, the bank BNK may surround at least a portion of an area for forming the sub-pixel area SPXA, and may protrude in a thickness direction (for example, in a third direction DR3) from the base layer BSL. Accordingly, the bank BNK may form a space in which the first color conversion layer CCL1, the second color conversion layer CCL2, and the scattering layer LSL may be disposed (for example, accommodated).

The bank BNK may cover the conductive pattern layer KEY configured to function as an alignment key, and may be configured to transmit the light applied by the exposure device 100. The bank BNK may have a light transmittance, and thus light for obtaining position information of the conductive pattern layer KEY to proceed with the exposure process may appropriately transmit through the bank BNK.

For example, the bank BNK may have a light transmittance of about 10% or more with respect to light of the NIR wavelength band. According to an embodiment, the bank BNK may have a light transmittance in a range of about 13% to about 20% with respect to the light of the NIR wavelength band (for example, light having a wavelength of about 880 nm). According to an embodiment, the bank BNK may have a light transmittance in a range of about 13% to about 15% with respect to the light of the NIR wavelength band (for example, light having a wavelength of about 880 nm). Here, the NIR wavelength band may include about 880 nm.

The light transmittance defined in this specification may be measured using a UV-VIS spectrophotometer.

According to an embodiment, in case that the light transmittance of the bank BNK satisfies at least one of the above-described numerical ranges, the exposure device 100 may be able to recognize the position of the conductive pattern layer KEY, and thus the exposure process may be performed appropriately.

The bank BNK may be a scattering bank. For example, the bank BNK may include a bank base BBS and a bank scatterer BSC.

According to an embodiment, the bank BNK may include the bank scatterer BSC. The light applied to the bank BNK may be recycled to improve light output efficiency, and a luminance characteristic of the display device DD may be improved.

The bank base BBS may include a matrix material forming the bank BNK. The bank base BBS may be a base for including the bank scatterer BSC.

According to an embodiment, the bank base BBS may include a photosensitive material. For example, the bank base BBS may include various organic materials having photosensitivity.

The bank scatterer BSC may include a scattering material capable of scattering light provided from the display layer DL. The bank scatterer BSC may be provided by being dispersed in the bank base BBS.

According to an embodiment, the bank scatterer BSC may include at least one material from a group of titanium oxide (TiOₓ), silica (SiOₓ) (for example, a silica bead, hollow silica, and the like), zirconium oxide (ZrOₓ), aluminum oxide (AlₓO_{y}), indium oxide (InₓO_{y}), zinc oxide (ZnOₓ), tin oxide (SnOₓ), cerium oxide (CeOₓ), indium tin oxide (ITO), antimony tin oxide (ATO), and antimony oxide (SbₓO_{y}). For example, the bank scatterer BSC may include TiO₂. However, the disclosure may not be limited thereto.

The bank scatterer BSC may include bank scatterers BSC having different sizes. For example, the bank scatterer BSC may include a first bank scatterer BSC1 and a second bank scatterer BSC having different sizes.

According to an embodiment, the first bank scatterer BSC1 may have a first size. The second bank scatterer BSC2 may have a second size less than the first size.

In this specification, the size of the bank scatterer BSC may mean a largest diameter that may be defined by a particle for the bank scatterer BSC.

For example, in case that the bank scatterer BSC has an elliptical shape, the size of the bank scatterer BSC may be a semi-major axis of an ellipse. For example, in case that the bank scatterer BSC has a circular shape, the size of the bank scatterer BSC may be a diameter. For example, in case that the bank scatterer BSC has a shape including an irregular protruding structure, the size of the bank scatterer BSC may be a distance between ends most spaced apart from each other in a shape of the bank scatterer BSC.

According to an embodiment, the first size of the first bank scatterer BSC1 may be in a range of about 200 nm to about 300 nm. According to an embodiment, the first size of the first bank scatterer BSC1 may be in a range of about 220 nm to about 300 nm. According to an embodiment, the first size of the first bank scatterer BSC1 may be in a range of about 200 nm to about 250 nm. However, the disclosure may not be limited thereto.

According to an embodiment, the second size of the second bank scatterer BSC2 may be in a range of about 100 nm to about 200 nm. The second size of the second bank scatterer BSC2 may be in a range of about 150 nm to about 200 nm. However, the disclosure may not be limited thereto.

According to the embodiment, in a case where each of the first bank scatterer BSC1 and the second bank scatterer BSC2 satisfies at least one of the above-described numerical ranges, in case that the exposure process proceeds as the bank BNK has a light transmittance, since the conductive pattern layer KEY may appropriately perform the function of the alignment key and have a reflectance, the light output efficiency of the display device DD may be improved.

For example, the first bank scatterer BSC1 may have a relatively large size, and thus may have a relatively high reflectance with respect to light applied from the light emitting element LD. Accordingly, the first bank scatterer BSC1 may enable the bank BNK to function as a scattering bank.

For example, the second bank scatterer BSC2 may have a relatively small size, and thus may have a relatively high transmittance with respect to the light of the NIR wavelength band.

Experimentally, in case that the scatterer has a size that is half a wavelength of target light, a relatively large reflectance may occur. According to an embodiment, since the first bank scatterer BSC1 may be provided in the bank BNK, the bank BNK may have a high reflectance with respect to a wavelength band of light that may be to be provided by the display device DD, and since the second bank scatterer BSC2 may be provided in the bank BNK, the bank BNK may have a high transmittance with respect to a wavelength band of light to be transmitted during the exposure process.

The bank BNK may have a bank thickness BT. According to an embodiment, the bank thickness BT may be in a range of about 1 μm to about 15 μm. According to an embodiment, the bank thickness BT may be defined based on the thickness direction (for example, the third direction DR3) of the base layer BSL or a thickness direction of the conductive pattern layer KEY.

According to an embodiment, the bank scatterer BSC may be included in a range of about 1% by weight to about 60% by weight with respect to a solid content of the bank BNK. For example, the bank BNK may include a solvent and a solid content, and a content of the bank scatterer BSC may be defined based on the entire solid content. According to an embodiment, the content of the bank scatterer BSC may be a sum of a content of the first bank scatterer BSC1 and a content of the second bank scatterer BSC2. According to an embodiment, the solvent may include various organic solvents, and for example, the solvent may include PGMEA. However, the disclosure may not be limited thereto.

According to an embodiment, the bank thickness BT may be determined based on the content of the bank scatterer BSC. The content of bank scatterer BSC may be determined based on the bank thickness BT. For example, the bank thickness BT and the content of bank scatterer BSC may be determined dependently on each other.

According to an embodiment, as the bank thickness BT increases, light transmittance for the light of the NIR wavelength band may decrease and light reflectance for the light provided by the display device DD may increase. According to an embodiment, as the content of the bank scatterer BSC increases, the light transmittance for the light of the NIR wavelength band may decrease and the light reflectance for the light provided by the display device DD may increase. Accordingly, the bank thickness BT and the content of bank scatterer BSC may be required to be adjusted.

According to an embodiment, the bank thickness BT may be in a range of about 10 μm to about 11 μm, and the bank scatterer BSC may be included in a range of about 6% by weight to about 7% by weight with respect to the solid content of the bank BNK.

According to an embodiment, the bank thickness BT may be in a range of about 4 μm to about 6 μm, and the bank scatterer BSC may be included in a range of about 12% by weight to about 16% by weight with respect to the solid content of the bank BNK.

According to an embodiment, the bank thickness BT may be in a range of about 2 μm to about 4 μm, and the bank scatterer BSC may be included in a range of about 20% by weight to about 24% by weight with respect to the solid content of the bank BNK.

According to an embodiment, the bank thickness BT may be in a range of about 0.5 μm to about 1.5 μm, and the bank scatterer BSC may be included in a range of about 60% by weight or less with respect to the solid content of the bank BNK. For example, the bank thickness BT may be in a range of about 0.5 μm to about 1.5 μm, and the bank scatterer BSC may be included in a range of about 0.01% by weight to about 60% by weight with respect to the solid content of the bank BNK.

According to an embodiment, in case that the bank thickness BT and the content of the bank scatterer BSC satisfy at least one of the above-described numerical ranges, the bank BNK may have an excellent light transmission characteristic with respect to the NIR wavelength band, and may have an excellent reflectance with respect to the light provided by the display device DD.

According to an embodiment, the color conversion layer CCL may be disposed on the light-emitting-element layer LEL (for example, the light emitting element LD). The color conversion layer CCL may be configured to change a wavelength of light. According to an embodiment, the first to third sub-pixels SPX1, SPX2, and SPX3 may include light emitting elements LD emitting light of the same color. For example, the first to third sub-pixels SPX1, SPX2, and SPX3 may include light emitting elements LD emitting light of a third color (or blue). As the color conversion layer CCL respectively including color conversion particles may be disposed on the first to third sub-pixels SPX1, SPX2, and SPX3, a full-color image may be displayed.

However, the color of light emitted by the light emitting element LD may not be limited to the above-described example. For convenience of description, the disclosure may be described based on an embodiment in which the light emitting element LD of each of the sub-pixels SPX emits blue light.

The first color conversion layer CCL1 may include first color conversion particles that convert the light of the third color emitted from the light emitting element LD into the light of the first color. For example, the first color conversion layer CCL1 may include multiple first quantum-dots QD1 dispersed in a matrix material such as a base resin.

According to an embodiment, in case that the light emitting element LD is a blue light emitting element emitting blue light and the first sub-pixel SPX1 is a red pixel, the first color conversion layer CCL1 may include a first quantum-dot QD1 converting the blue light emitted from the blue light emitting element into red light. The first quantum-dot QD1 may absorb the blue light and emit the red light by shifting a wavelength according to an energy transition. According to an embodiment, in case that the first sub-pixel SPX1 is a pixel of another color, the first color conversion layer CCL1 may include a first quantum-dot QD1 corresponding to the color of the first sub-pixel SPX1.

The second color conversion layer CCL2 may include second color conversion particles that convert the light of the third color emitted from the light emitting element LD into the light of the second color. For example, the second color conversion layer CCL2 may include multiple second quantum-dots QD2 dispersed in a matrix material such as a base resin.

According to an embodiment, in case that the light emitting element LD is the blue light emitting element emitting the blue light and the second sub-pixel SPX2 is a green pixel, the second color conversion layer CCL2 may include a second quantum-dot QD2 converting the blue light emitted from the blue light emitting element into green light. The second quantum-dot QD2 may absorb the blue light and emit the green light by shifting a wavelength according to an energy transition. According to an embodiment, in case that the second sub-pixel SPX2 is a pixel of another color, the second color conversion layer CCL2 may include a second quantum-dot QD2 corresponding to the color of the second sub-pixel SPX2.

According to an embodiment, as the blue light having a relatively short wavelength in a visible ray spectrum may be incident on each of the first quantum-dot QD1 and the second quantum-dot QD2, an absorption coefficient of the first quantum-dot QD1 and the second quantum-dot QD2 may be increased. Accordingly and finally, efficiency of light emitted from the first sub-pixel SPX1 and the second sub-pixel SPX2 may be improved and excellent color reproducibility may be secured. Since the first to third sub-pixels SPX1, SPX2, and SPX3 are formed by using the light emitting elements LD of the same color (for example, the blue light emitting element), manufacturing efficiency of the display device DD may be increased.

The scattering layer LSL may be provided to efficiently use the light of the third color (or blue) emitted from the light emitting element LD. For example, in case that the light emitting element LD is the blue light emitting element emitting the blue light and the third sub-pixel SPX3 is a blue pixel, the scattering layer LSL may include at least one type of scatterer SCT in order to efficiently use the light emitted from the light emitting element LD. For example, the scatterer SCT of the scattering layer LSL may include various light scattering particles or light scattering materials. For example, the scatterer may include one or more of the examples described above with reference to the bank scatterer BSC.

According to an embodiment, the scatterer SCT may be disposed in a sub-pixel in addition to the third sub-pixel SPX3, and may be selectively included in the first color conversion layer CCL1 or the second color conversion layer CCL2. According to an embodiment, the scatterer SCT may be omitted, and thus the scattering layer LSL including a transparent polymer may be provided.

The second capping layer CPL2 may be disposed on each of the first color conversion layer CCL1, the second color conversion layer CCL2, and the scattering layer LSL, and may cap each of the first color conversion layer CCL1, the second color conversion layer CCL2, and the scattering layer LSL.

According to an embodiment, the second capping layer CPL2 may be provided over the first to third sub-pixels SPX1, SPX2, and SPX3. According to an embodiment, the second capping layer CPL2 may be an inorganic layer, and may include at least one of a group of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}). However, the disclosure may not be limited thereto.

The cover layer CL may be disposed on the quantum-dot layer QL. According to an embodiment, the light provided from the display layer DL may pass through the cover layer CL and may be emitted to an outside.

According to an embodiment, the cover layer CL may include a window. According to an embodiment, an example of the cover layer CL may not be particularly limited. For example, the cover layer CL may further include a color filter. The cover layer CL may further include an anti-reflection film (or structure). The cover layer CL may further include a lens layer.

Below, an experimental example related to a technical effect according to the disclosure is described based on an embodiment and a comparative example. However, the following embodiment and comparative example may only be examples to describe the disclosure in more detail, and the disclosure may not be necessarily limited by the following embodiment and comparative example.

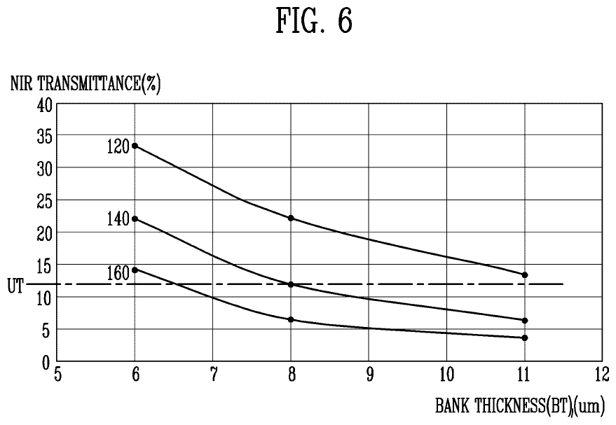

Experimental Example 1 was prepared to describe a light transmittance tendency of the bank BNK according to the bank thickness BT and the content of the bank scatterer BSC. A result according to Experimental Example 1 is shown in FIG. 6. FIG. 6 is a graph illustrating Experimental Example 1.

In order to perform Experimental Example 1, banks BNK according to Manufacturing Example 1-1, Manufacturing Example 1-2, and Manufacturing Example 1-3 were manufactured.

The bank BNK according to Manufacturing Example 1-1 was manufactured so that TiO₂ having a size of about 220 nm as the bank scatterer BSC was included in about 6% by weight with respect to the solid content of the bank BNK.

The bank BNK according to Manufacturing Example 1-2 was manufactured so that TiO₂ having a size of about 220 nm as the bank scatterer BSC was included in about 8% by weight with respect to the solid content of the bank BNK.

The bank BNK according to Manufacturing Example 1-3 was manufactured so that TiO₂ having a size of about 220 nm as the bank scatterer BSC was included in 10% by weight with respect to the solid content of the bank BNK.

Under a room temperature (about 25° C.) environment, a light transmittance was measured by differentiating the bank thickness BT of the manufactured banks BNK and applying light having a wavelength band of about 880 nm. As a light application device, SHIMADZU company's UV-3600I product was used, and in order to measure the light transmittance, Minolta company's CA-130 product was used.

In FIG. 6, a (1-1)-th graph 120 illustrates a light transmittance according to the bank thickness BT of the bank BNK according to Manufacturing Example 1-1. In FIG. 6, a (1-2)-th graph 140 illustrates a light transmittance according to the bank thickness BT of the bank BNK according to Manufacturing Example 1-2. In FIG. 6, a (1-3)-th graph 160 illustrates a light transmittance according to the bank thickness BT of the bank BNK according to Manufacturing Example 1-3.

Referring to FIG. 6, it may be seen that as the bank thickness BT increases, a transmittance of the bank BNK to light of the NIR wavelength band decreases. It may further be seen that as the content of the bank scatterer BSC increases, the transmittance of the bank BNK to light of the NIR wavelength band decreases.

As described above, in order for the conductive pattern layer KEY to appropriately function as the alignment key, the bank BNK may be required to have a light transmittance. For example, in case that the bank BNK has a light transmittance equal to or greater than the target transmittance UT, in a case where the conductive pattern layer KEY may function as the alignment key, the bank BNK may be preferably prepared to have the bank thickness BT and the content of the bank scatterer BSC defined above a line representing the target transmittance UT.

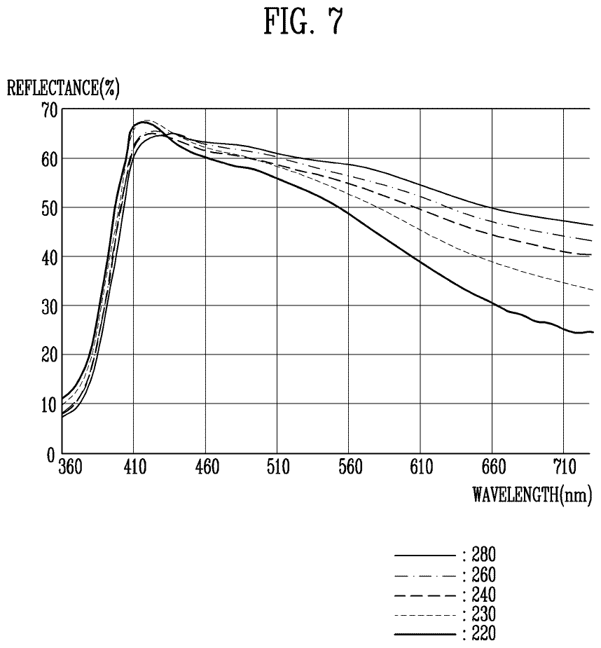

Experimental Example 2 was prepared to describe a light transmittance tendency of the bank BNK according to a wavelength of light applied to the bank BNK. A result according to Experimental Example 2 is shown in FIG. 7. FIG. 7 is a graph illustrating Experimental Example 2.

In order to perform Experimental Example 2, banks BNK according to Manufacturing Example 2-1, Manufacturing Example 2-2, and Manufacturing Example 2-3 were manufactured.

The bank BNK according to Manufacturing Example 2-1 was manufactured so that TiO₂ having a size of about 170 nm as the bank scatterer BSC was included in about 10% by weight with respect to the solid content of the bank BNK.

The bank BNK according to Manufacturing Example 2-2 was manufactured so that TiO₂ having a size of about 300 nm as the first bank scatterer BSC1 was included in about 5% by weight with respect to the solid content of the bank BNK, and TiO₂ having a size of about 170 nm as the second bank scatterer BSC2 was included in about 5% by weight with respect to the solid content of the bank BNK.

The bank BNK according to Manufacturing Example 2-3 was manufactured so that TiO₂ having a size of about 300 nm as the first bank scatterer BSC1 was included in about 7% by weight with respect to the solid content of the bank BNK, and TiO₂ having a size of about 170 nm as the second bank scatterer BSC2 was included in about 3% by weight with respect to the solid content of the bank BNK.

The bank BNK according to Manufacturing Example 2-4 was manufactured so that TiO₂ having a size of about 300 nm as the first bank scatterer BSC1 was included in about 9% by weight with respect to the solid content of the bank BNK, and TiO₂ having a size of about 170 nm as the second bank scatterer BSC2 was included in about 1% by weight with respect to the solid content of the bank BNK.

The bank BNK according to Manufacturing Example 2-5 was manufactured so that TiO₂ having a size of about 300 nm as the bank scatterer BSC was included in about 10% by weight with respect to the solid content of the bank BNK.

Light of various wavelength bands was applied to the manufactured banks BNK and a light reflectance was measured. As a light application device, SHIMADZU company's UV-3600I product was used, and in order to measure the light transmittance, Minolta company's CA-130 product was used.

In FIG. 7, a (2-1)-th graph 220 illustrates a light reflectance according to the wavelength of the light applied to the bank BNK according to Manufacturing Example 2-1. In FIG. 7, a (2-2)-th graph 230 illustrates a light reflectance according to the wavelength of the light applied to the bank BNK according to Manufacturing Example 2-2. In FIG. 7, a (2-3)-th graph 240 illustrates a light reflectance according to the wavelength of the light applied to the bank BNK according to Manufacturing Example 2-3. In FIG. 7, a (2-4)-th graph 260 illustrates a light reflectance according to the wavelength of the light applied to the bank BNK according to Manufacturing Example 2-4. In FIG. 7, a (2-5)-th graph 280 illustrates a light reflectance according to the wavelength of the light applied to the bank BNK according to Manufacturing Example 2-5.

Referring to FIG. 7, it may be seen that in a relatively low wavelength band (for example, a wavelength band of about 450 nm or less), the bank BNK may have a higher reflectance as the content of the second bank scatterer BSC2 having a relatively small size increases. It may be seen that in a visible light wavelength band (for example, in a range of about 450 nm to about 700 nm), the bank BNK may have a higher reflectance as the content of the first bank scatterer BSC1 having a relatively large size increases.

As described above, the bank BNK according to an embodiment may be required to have a high reflectance at a relatively low wavelength band including the visible light wavelength band. In connection with FIG. 7, the above-described technical characteristic may be secured as the first bank scatterer BSC1 and the second bank scatterer BSC2, of which sizes may be different from each other, may be included in the bank BNK.

Experimental Example 3 was prepared to describe a technical effect in which a light transmittance characteristic and a reflectance characteristic may be improved by including the first bank scatterer BSC1 and the second bank scatterer BSC2 having different sizes in the bank BNK according to an embodiment. A result according to Experimental Example 3 is shown in [Table 1].

In order to perform Experimental Example 3, banks BNK according to Comparative Example, Manufacturing Example 3-1, Manufacturing Example 3-2, Manufacturing Example 3-3, and Manufacturing Example 3-4 were manufactured. Experimental Example 3 is for describing a characteristic of a structure in which the first and second bank scatterers BSC1 and BSC2 having different sizes may be included in the bank BNK. For convenience of description, a bank BNK including bank scatterers BSC of relatively uniform size was referred to as Comparative Example.

The bank BNK according to Comparative Example was manufactured so that TiO₂ having a size of about 220 nm as the bank scatterer BSC was included in about 6% by weight with respect to the solid content of the bank BNK.

The bank BNK according to Manufacturing Example 3-1 was manufactured so that TiO₂ having a size of about 220 nm as the first bank scatterer BSC1 was included in about 3% by weight with respect to the solid content of the bank BNK, and TiO₂ having a size of about 170 nm as the second bank scatterer BSC2 was included in about 4% by weight with respect to the solid content of the bank BNK.

The bank BNK according to Manufacturing Example 3-2 was manufactured so that TiO₂ having a size of about 220 nm as the first bank scatterer BSC1 was included in about 4% by weight with respect to the solid content of the bank BNK, and TiO₂ having a size of about 170 nm as the second bank scatterer BSC2 was included in about 3% by weight with respect to the solid content of the bank BNK.

The bank BNK according to Manufacturing Example 3-3 was manufactured so that TiO₂ having a size of about 220 nm as the first bank scatterer BSC1 was included in about 5% by weight with respect to the solid content of the bank BNK, and TiO₂ having a size of about 170 nm as the second bank scatterer BSC2 was included in about 2% by weight with respect to the solid content of the bank BNK.

The bank BNK according to Manufacturing Example 3-4 was manufactured so that TiO₂ having a size of about 220 nm as the first bank scatterer BSC1 was included in about 3% by weight with respect to the solid content of the bank BNK, and TiO₂ having a size of about 170 nm as the second bank scatterer BSC2 was included in about 3% by weight with respect to the solid content of the bank BNK.

With respect to the manufactured banks BNK, an integrating sphere reflectance was measured, and a transmittance for the NIR wavelength band (about 880 nm) was measured.

In order to measure each of the integrating sphere reflectance and the light transmittance, SHIMADZU company's UV-3600I product was used as a light application device, and Minolta company's CA-130 product was used as a device for light characteristic measurement.

TABLE 1

| | Integrating sphere | Transmittance for NIR wavelength |
|---|---|---|
| Division | reflectance (%) | band (%) |
| Comparative | 13.72 | 14.7 |
| Example | | |
| Manufacturing | 17.90 | 14.8 |
| Example 3-1 | | |
| Manufacturing | 17.40 | 14.1 |
| Example 3-2 | | |
| Manufacturing | 17.40 | 13.0 |
| Example 3-3 | | |
| Manufacturing | 16.30 | 15.2 |
| Example 3-4 | | |

Referring to Table 1, it may be seen that compared to the comparative example in which the bank BNK includes only the bank scatterer BSC of a relatively uniform size, in case that the bank BNK includes the first bank scatterer BSC1 and the second bank scatterer BSC2 of different sizes according to an embodiment, the integrating sphere reflectance is excellent and the transmittance for the NIR wavelength band is improved.

As described above, although the disclosure has been described with reference to the embodiment above, those skilled in the art or those having a common knowledge in the art will understand that the disclosure may be variously modified and changed without departing from the spirit and technical area of the disclosure described in the claims which will be described later. Therefore, the technical scope of the disclosure should not be limited to the contents described in the detailed description of the specification, but should be defined by the claims.

What is claimed is:

1. A display device comprising:
a base layer;
a display layer disposed on the base layer and including a light emitting element;
a conductive pattern layer disposed on the display layer; and
a bank disposed on the display layer, the bank protruding in a thickness direction of the base layer, and the bank surrounding at least a portion of an area,
wherein the bank covers the conductive pattern layer, the bank including a first bank scatterer and a second bank scatterer, the second bank scatterer having a size different from that of the first bank scatterer.

2. The display device according to claim 1, wherein the bank transmits light of a near infrared wavelength band.

3. The display device according to claim 2, wherein the bank has a light transmittance in a range of about 13% to about 15% with respect to light having a wavelength of about 880 nm.

4. The display device according to claim 1, wherein the bank includes a bank base including a photosensitive material.

5. The display device according to claim 1, wherein each of the first bank scatterer and the second bank scatterer includes at least one material selected from a group of titanium oxide (TiOₓ), silica (SiOₓ) (for example, a silica bead, hollow silica, and the like), zirconium oxide (ZrOₓ), aluminum oxide (AlO_{y}), indium oxide (InₓO_{y}), zinc oxide (ZnOₓ), tin oxide (SnOₓ), cerium oxide (CeOₓ), indium tin oxide (ITO), antimony tin oxide (ATO), and antimony oxide (SbₓO_{y}).

6. The display device according to claim 1, wherein a size of the first bank scatterer is in a range of about 200 nm to about 300 nm.

7. The display device according to claim 1, wherein a size of the second bank scatterer is in a range of about 100 nm to about 200 nm.

8. The display device according to claim 1, wherein
the bank has a thickness in a range of about 10 μm to about 11 μm, and
each of the first bank scatterer and the second bank scatterer are included in a range of about 6% by weight to about 7% by weight with respect to a solid content of the bank.

9. The display device according to claim 1, wherein
the bank has a thickness in a range of about 4 μm to about 6 μm, and
each of the first bank scatterer and the second bank scatterer is included in a range of about 12% by weight to about 16% by weight with respect to a solid content of the bank.

10. The display device according to claim 1, wherein
the bank has a thickness in a range of about 2 μm to about 4 μm, and
each of the first bank scatterer and the second bank scatterer is included in a range of about 20% by weight to about 24% by weight with respect to a solid content of the bank.

11. The display device according to claim 1, wherein
the bank has a thickness in a range of about 0.5 μm to about 1.5 μm, and
each of the first bank scatterer and the second bank scatterer is included in a range of about 0.01% by weight to about 60% by weight with respect to a solid content of the bank.

12. The display device according to claim 1, wherein the conductive pattern layer functions as an alignment key during an exposure process for manufacturing the display device.

13. The display device according to claim 1, further comprising:
a color conversion layer disposed in the area surrounded by the bank, the color conversion layer including a quantum-dot.

14. The display device according to claim 1, further comprising:
sub-pixels forming sub-pixel areas where light of a color is respectively provided, wherein
the sub-pixel areas include a first sub-pixel area, a second sub-pixel area, and a third sub-pixel area,
the sub-pixels include a first sub-pixel, a second sub-pixel, and a third sub-pixel,
the bank is disposed between the sub-pixel areas, and
the display device further comprises:
a first color conversion layer disposed in the first sub-pixel area and including a first quantum-dot;
a second color conversion layer disposed in the second sub-pixel area and including a second quantum-dot; and
a scattering layer disposed in the third sub-pixel area and including a scatterer.

15. The display device according to claim 1, wherein the conductive pattern layer and the bank are in contact with each other.

16. The display device according to claim 1, wherein the area corresponds to one of a color conversion layer and a scattering layer.

17. The display device according to claim 12, wherein the bank simultaneously increases reflectance of a visible light produced by the display layer and transmits a near infrared light to detect a location of the alignment key by detecting a reflection of the near infrared light from the alignment key.

18. The display device according to claim 1, wherein
a size of the first bank scatterer is in a range of about 200 nm to about 300 nm, and
a size of the second bank scatterer is in a range of about 100 nm to about 200 nm.
